(19) United States
(12) Patent Application Publication
(10) Pub. No.: US 2004/0048464 A1
(43) Pub. Date: Mar. 11, 2004

(54) Semiconductor device having a planarized structure and the method for producing the same

(76) Inventor: Yoo-Jeong Park, Kwangju-shi (KR)

Correspondence Address: LATHROP & GAGE LC, 2345 GRAND AVENUE, SUITE 2800, KANSAS CITY, MO, 64108, US

(21) Appl. No.: 10/367,487

(22) Filed: Feb. 14, 2003

(30) Foreign Application Priority Data
Feb. 16, 2002 (KR) 10-2002-8330

(51) Int. Cl. H01L 21/44; H01L 21/331; H01L 21/8222

(52) U.S. Cl. 438/670; 438/612; 438/347; 438/309

(57) ABSTRACT

The present invention provides a method for producing semiconductor device having a planarized structure wherein elevational disparities are removed. The semiconductor is produced by forming insulation layer on the transistor device, coating the photo resist layer on the insulator layer, carrying out patterning so that the contact region is opened, forming the region on which the metal is mounted by removing the insulation layer of the contact region, depositing the electrode metal, and removing the photo resist layer by lift-off process.

### RELATED APPLICATIONS

This application claims the benefit of Korean Utility application Serial No. 10-2002-8330, filed Feb. 16, 2002 and incorporated herein by reference.

### TECHNICAL FIELD

The present invention relates to a semiconductor device having a planarized structure and a method for producing the semiconductor device. More particularly, the invention relates to a semiconductor device having a planarized structure in which elevational disparities are removed so that yield rate and reliability are increased in the post processing.

### BACKGROUND OF THE INVENTION

As semiconductors become highly integrated, the unit area of the cell is reduced, and the structure of the cell becomes more complex changing from a two-dimensional structure to a three-dimensional structure. As an example of the three-dimensional structure, COB (capacitor over bit line) structure has been used, in which stacked capacitors are formed on the bit line to ensure static capacity in DRAM. This complicated three-dimensional structure causes elevational disparity, the difference in the vertical height in the same plane, as shown in A and B portion of FIG. 1. This elevational disparity makes it difficult to perform subsequent processes, especially photolithographic process, and decreases the margin of the subsequent processes. In the DRAM employing a COB structure, elevational disparity occurs between cell area in which stacked capacitors are formed and peripheral region without stacked capacitors by 50% to 100% of the height of stacked capacitors. Because of elevational disparity, depth of focus margin decreases in the photolithographic process of the subsequent process of forming metal contact, and it is difficult to form contact patterns simultaneously in the cell area and in the peripheral region.

For example, in a device having design rule of 0.2 μm, the height of stacked capacitor is about 1 μm causing significant elevational disparity, which leads to many problems in the process of forming contact. In current photolithographic technique, it is very difficult to overcome the problem caused by elevational disparity.

A method for solving the problem is to decrease the elevational disparity through a planarizing insulation layer before exposing to light for forming a contact hole. However, the method of decreasing the elevational disparity by the planarizing the insulation layer increases the depth of the contact hole and increases the aspect ratio of the contact hole making it difficult to fill the contact hole with metal.

### SUMMARY OF THE INVENTION

One object of the present invention is to provide a method for producing semiconductor device having a planarized structure by removing elevational disparity caused by the overlapping of the contact and metal, metal and pad.

Another object of the present invention is to provide a method for producing semiconductor device, in which the number of masks in the manufacturing process is reduced by using lift-off process.

Yet another object of the present invention is to provide a method for producing semiconductor device, which does not generate over-etching.

Still another object of the present invention is to provide a method for producing semiconductor device, which can be applied to the structure that carries out bonding the chip directly onto the lead frame without wire-bonding.

To obtain these objects, the method for producing semiconductor device having a planarized structure according to the present invention comprises the steps of forming transistor devices on a substrate, forming insulation layer on the transistor devices, coating photo resist layer on the insulation layer, exposing the substrate by using a contact aligner and a contact mask, baking the substrate for more than 1 minute at the temperature of 100˜120° C. after the exposing step, developing after the baking step, etching in which the insulation layer of the contact region is removed to form the region on which metal is mounted, depositing first metal at the predetermined temperature after the etching step, removing the photo resist layer after first metal is deposited, forming the insulation layer with predetermined thickness, forming a bonding pad by removing insulation layer on part of the metal surface, and depositing secondary metal on the bonding pad.

According to another aspect of the present invention, the transistor device used is a bipolar junction transistor.

According to another detailed aspect of the present invention, the transistor device used is a Field Effect transistor.

According to still another detailed aspect of the present invention, the step of depositing first metal is carried out at the temperature of 80˜110° C. the thickness of the first metal being 1.0˜2.0 μm.

### BRIEF DESCRIPTION OF DRAWINGS

FIG. 1 illustrates elevational disparity of prior art semiconductor device,

FIG. 2 illustrates semiconductor device produced by using the method of the present invention,

FIG. 3 schematically illustrates the method for producing semiconductor device of the present invention, and

FIGS. 4 through 10 illustrate steps of the method for producing semiconductor device according to the present invention.

### DETAILED DESCRIPTION OF EXAMPLARY EMBODIMENT

The method for producing semiconductor device according to the present invention will now be described in detail with references to the attached drawings.

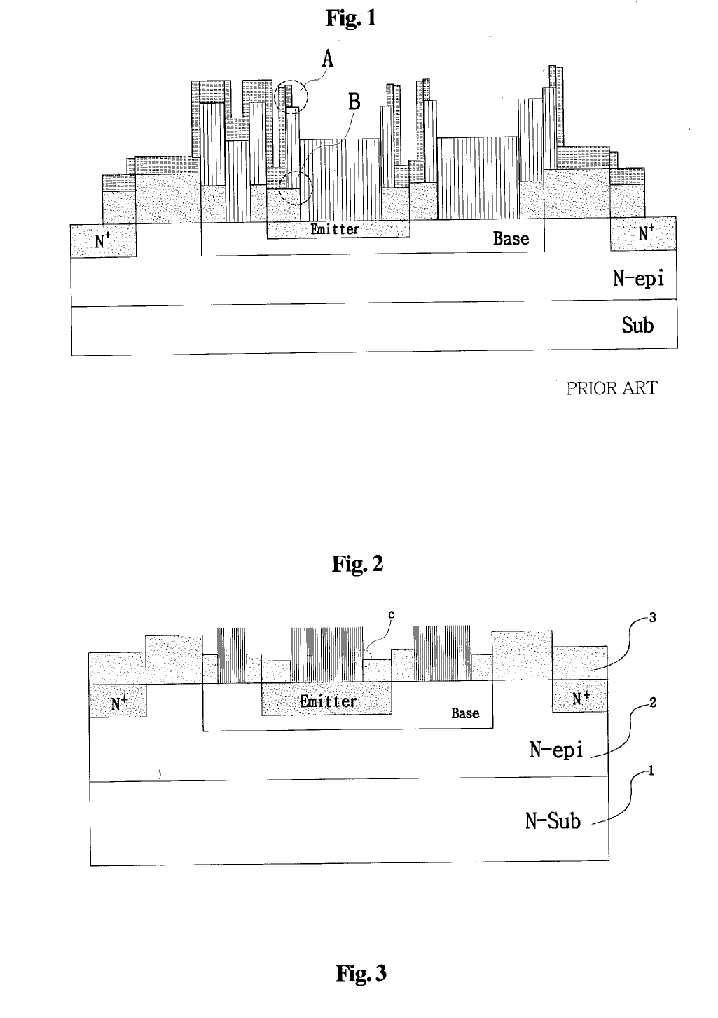

FIG. 2 illustrates a semiconductor device produced by using the method of the present invention. As can be seen in the region C, the elevational disparity apparent in FIG. 1 is removed since no overlapping of contact and metal.

FIG. 3 schematically illustrates the method for producing semiconductor device having planarized structure according to the present invention. The method of the present invention can be applied to bipolar transistor of NPN type or PNP type and to Field Effect Transistor. In this embodiment, bipolar transistor of NPN type is used as an example.

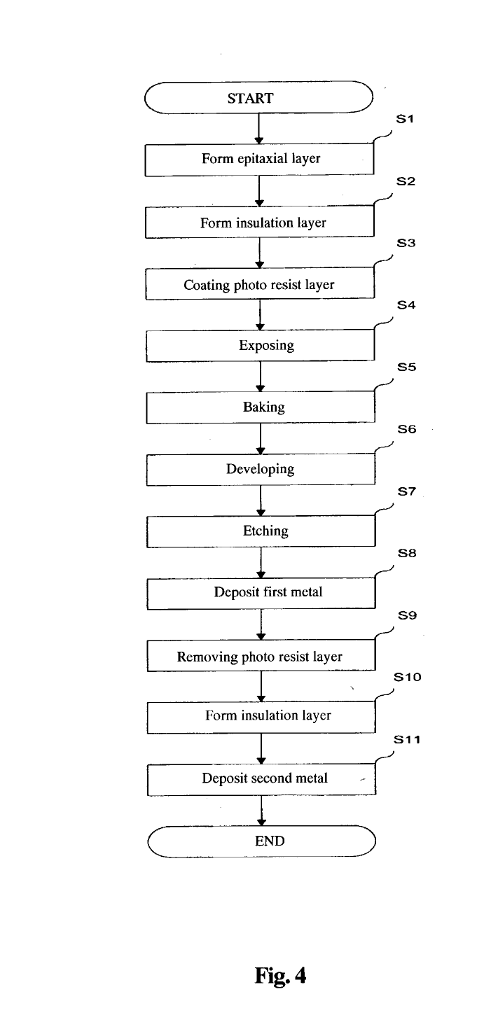

First, an epitaxial layer 2 in which N type impurities are doped on the N type substrate 1 is formed as in FIG. 4. Here, the epitaxial layer is a collector region of the bipolar transistor. On the top of the epitaxial layer, a base region in which P type impurities are doped is formed. Also, inside the base region, an emitter region in which N type impurities are doped is formed. And, a well area in which N type impurities are doped with high concentration is formed at both sides of the base region on the top of the epitaxial layer. When there is one bipolar device unit, the well area is removed in the following process. When several bipolar device units are simultaneously formed on the top of the substrate, the well area can be used for separating the device unit area. On the surface of the epitaxial layer is formed an insulator layer (oxidation layer) 3 which is composed of insulation material such as silicon oxide or silicon nitride. On the insulation layer, an opening or contact is formed to open emitter region and base region (S2 step). Then, photo resist layer 4 for lift-off process is coated on the whole surface of the wafer. The thickness of the photo resist layer is set to be 2 or 3 times that of the metal to be mounted. In this embodiment the thickness of the photo resist layer is set to 3 μm (S3 step).

After S3 step, exposing step is carried out by using contact aligner and contact mask (S4 step), and then baking is carried out at 110° C. for 1 minute (S5 step). Then patterning process is finished by carrying out developing step and the contact area is opened (S6 step).

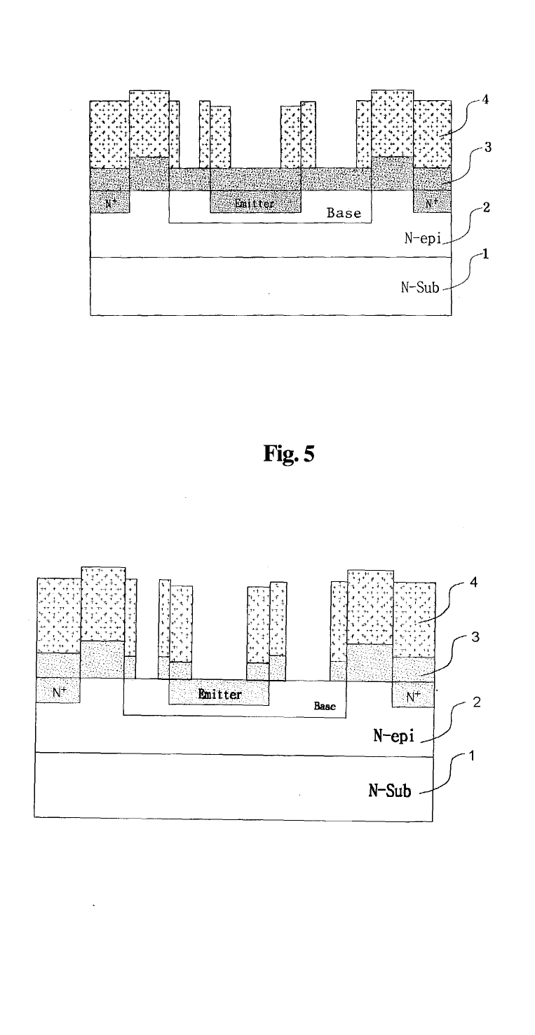

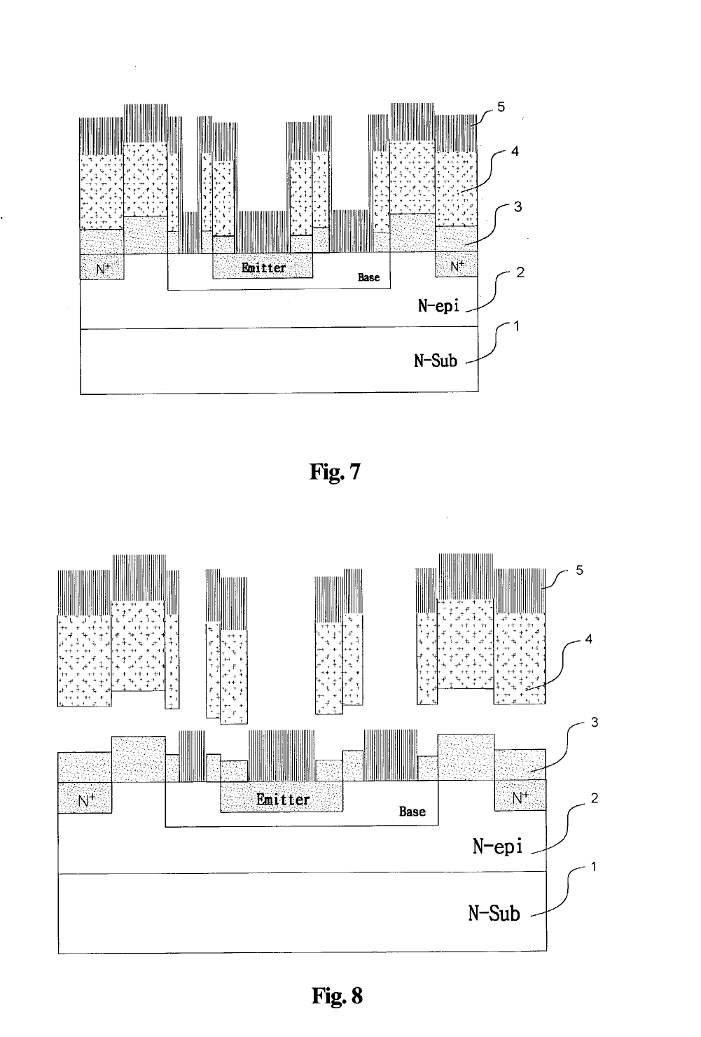

After finishing the patterning process, etching is carried out and the insulation layer (oxidation layer) on the contact area is removed so that metal can be mounted, as shown in FIG. 5 (S7 step). After finishing the etching step (existence of photo resist), metal is deposited with the thickness of 1.5 μm at room temperature or at predetermined temperature (100° C.) by using depositing device, as in FIG. 6. The depositing temperature is determined so that the profile of photo resist layer is not destroyed and the lift-off feature remains good. Due to the elevational disparities of the patterned photo resist layer, the thickness of metal deposited becomes very thin on the side area except the contact region (S8 step).

When metal deposition is completed, the photo resist layer is removed by lift-off method (S9 step). Photo resist layer removing solution can be used in this step. When the photo resist layer is removed, the metal on the layer is also removed and separate process for etching metal is not necessary.

After the photo resist layer is removed by lift-off method, the elevational disparities between contact and metal are removed, as can be seen in FIG. 8.

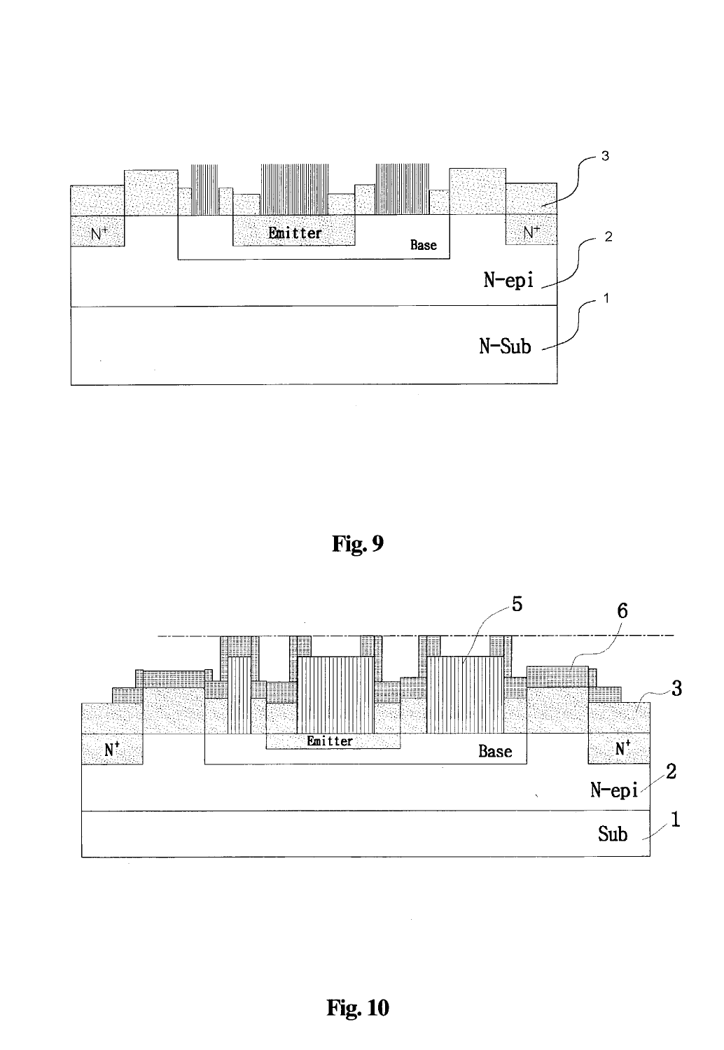

Then insulation layer 6 is formed with predetermined thickness as in FIG. 9 (S10 step), and part of insulation layer on the metal surface is removed to form bonding pad.

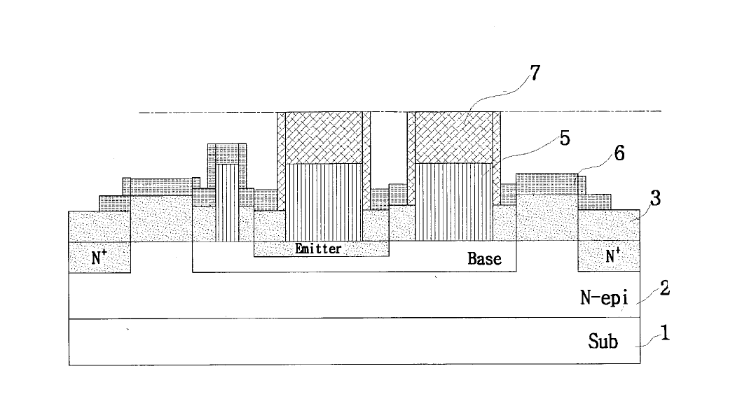

A second metal 7 is deposited on the above bonding pad as shown in FIG. 10 (S11 step). It can be seen that the elevational disparities between contact and metal due to the overlapping of metal and pad in prior art, as shown as A of FIG. 1, are removed.

When the method of present invention is employed, extra metal mask is not necessary since the contact consists of metal, so the number of masks can be reduced. Also, it is possible to produce semiconductor chip having planarized structure with low cost since there is no need for expensive equipments such as CMP (chemical mechanical polishing) device. In addition, the production process can be simplified reducing the cost of production further.

As described above, by using the method of the present invention, semiconductor device having a planarized structure can be produced by removing elevational disparities generated in the conventional method of prior art. Due to the planarized structure of the semiconductor device, short or leakage after wire bonding process can be prevented. The method of the present invention can be applied to the process in which the chip is directly bonded onto the lead frame without wire bonding.

What is claimed is:

1. A method for producing a semiconductor device having a planarized structure comprises the steps of:
forming transistor devices on a substrate;
forming an insulation layer on the transistor devices;
coating a photo resist layer on the insulation layer;
exposing the substrate by using a contact aligner and a contact mask;
baking the substrate for more than 1 minute at the temperature of 100˜120° C. after the exposing step;
developing after the baking step;
etching in which the insulation layer of a contact region is removed to form a region on which metal is mounted;
depositing first metal at the predetermined temperature after the etching step;
removing the photo resist layer after first metal is deposited;
forming the insulation layer with predetermined thickness;
forming a bonding pad by removing insulation layer on part of the metal surface; and
depositing a secondary metal on the bonding pad.

2. The method for producing semiconductor device having a planarized structure according to claim 1, wherein the transistor device is a bipolar junction transistor.

3. The method for producing semiconductor device having a planarized structure according to claim 1, wherein the transistor device is a Field Effect transistor.

4. The method for producing semiconductor device having a planarized structure according to claim 1, wherein the step of depositing first metal is carried out at the temperature of 80˜110° C. the thickness of the first metal being 1.0˜2.0 μm.

5. The semiconductor device having a planarized structure produced by one of the methods of claim 1.

6. The method for producing semiconductor device having a planarized structure according to claim 1, wherein the transistor device is a bipolar junction transistor.

7. The method for producing semiconductor device having a planarized structure according to claim 1, wherein the transistor device is a Field Effect transistor.

8. The method for producing semiconductor device having a planarized structure according to claim 1, wherein the step of depositing first metal is carried out at the temperature of 80˜110° C. the thickness of the first metal being 1.0˜2.0 μm.
